(19) United States
(12) Patent Application Publication
(10) Pub. No.: US 2011/0269413 A1
(43) Pub. Date: Nov. 3, 2011

(54) Circuit board and method for manufacturing the same

(75) Inventors: Seung Wook Park, Suwon (KR); Young Do Kweon, Seoul (KR); Mi Jin Park, Suwon (KR)

(73) Assignee: Samsung Electro-Mechanics Co., Ltd., Suwon (KR)

(21) Appl. No.: 12/926,280

(22) Filed: Nov. 5, 2010

(30) Foreign Application Priority Data
Apr. 30, 2010 (KR) 10-2010-0040465

(51) Int. Cl. H04B 1/38; H05K 3/30

(52) U.S. Cl. 455/90.2; 29/832

(57) ABSTRACT

There are provided a circuit board and a method for manufacturing the same. The circuit board according to the present invention includes: a first wiring pattern that is formed on one surface of the board; a second wiring pattern that is formed on the other surface of the board; an RF transmitter that is formed on one surface of the board and is connected to the first wiring pattern; and an RF receiver that is formed on the other surface of the board to be paired with the RF transmitter and is connected to the second wiring pattern, wherein the first wiring pattern and the second wiring pattern are electrically connected to each other by wireless communication from the RF transmitter to the RF receiver.

### CROSS-REFERENCE TO RELATED APPLICATIONS

This application claims the priority of Korean Patent Application No. 10-2010-0040465 filed on Apr. 30, 2010, in the Korean Intellectual Property Office, the disclosure of which is incorporated herein by reference.

### BACKGROUND OF THE INVENTION

1. Field of the Invention

The present invention relates to a circuit board, and more particularly, to a circuit board capable of making a connection between the upper and lower surfaces of the circuit board in a contactless manner by connecting wiring patterns formed on both surfaces of the circuit board using wireless communication.

2. Description of the Related Art

In the circuit board according to the related art or a multi-layer ceramic board formed by stacking a plurality of ceramic sheets, wiring patterns are formed on the upper and lower surfaces of a circuit board or on each surface of the plurality of ceramic sheets.

The circuit board or multi-layer ceramic board according to the related art is provided with surface mountable electronic components such as semiconductor devices, a chip stacking condenser, and so on, wherein the surface mountable electronic components are alternately disposed on the circuit board.

Therefore, in order to electrically connect the wiring patterns and the electronic components, a conductive via such as a through silicon via (TSV) or a laser via has been used in the circuit board or the multi-layer ceramic board.

However, when the TSV is used, a through hole is formed in each layer by using an etching process or a laser drilling process and a via conductor is formed in the through hole by using a via plating process, such that the manufacturing process becomes complicated and the cost for each process is high, thereby degrading production efficiency.

In addition, although the laser via has been used in a typical printed circuit board (PCB), it is difficult to precisely process the laser via.

### SUMMARY OF THE INVENTION

An aspect of the present invention provides a circuit board having a simple manufacturing process and low manufacturing costs by connecting both surfaces of a board and each layer of a multi-layer ceramic board in a contactless manner by wireless communication between pairs of RF transmitters and RF receivers provided on both surfaces of the circuit board and each layer of the multi-layer ceramic board.

According to an aspect of the present invention, there is provided a circuit board, including: a first wiring pattern that is formed on one surface of the board; a second wiring pattern that is formed on the other surface of the board; an RF transmitter that is formed on one surface of the board and is connected to the first wiring pattern; and an RF receiver that is formed on the other surface of the board to be paired with the RF transmitter and is connected to the second wiring pattern, wherein the first wiring pattern and the second wiring pattern are electrically connected to each other by wireless communication from the RF transmitter to the RF receiver.

The RF transmitter may be an antenna and the RF receiver may be a transceiver.

The RF receiver may be formed at a position corresponding to the position of the RF transmitter.

The circuit board may further include a cavity that is formed toward the inner side of the board from at least one of one surface and the other surface of the board, wherein a passive device may be embedded in the cavity.

A protective layer may be formed on the upper and lower surfaces of the board to cover the first wiring pattern, the second wiring pattern, the RF transmitter, and the RF receiver.

According to another aspect of the present invention, there is provided a circuit board, including: a plurality of ceramic sheets that are sequentially stacked; a plurality of wiring patterns that are formed on any one of the plurality of ceramic sheets; an RF transmitter that is connected to a wiring pattern formed on one of any ceramic sheets and transmits signals from a wiring pattern formed on one sheet; and an RF receiver that is connected to a wiring pattern formed on the other sheet of any ceramic sheets and is formed at a position corresponding to the RF transmitter to receive signals from the RF transmitter and transmit them to the wiring pattern formed on the other sheet.

One sheet may be a ceramic sheet that forms the top layer of the plurality of ceramic sheets, the other sheet may be a ceramic sheet that forms the bottom layer of the plurality of ceramic sheets, and the electrical signals between the wiring pattern formed on the ceramic sheet that forms the top layer and the wiring pattern formed on the ceramic sheet that forms the bottom layer may be exchanged with each other by wireless communication from the RF transmitter to the RF receiver.

According to another aspect of the present invention, there is provided a method for manufacturing a circuit board, including: forming a first wiring pattern and an RF transmitter connected to the first wiring pattern on one surface of a board; and forming a second wiring pattern and an RF receiver connected to the second wiring pattern and formed to be paired with the RF transmitter on the other surface of the board, wherein the first wiring pattern is electrically connected to the second wiring pattern by wireless communication from the RF transmitter to the RF receiver.

The method for manufacturing a circuit board may further include: forming a cavity toward the inner side of the board from at least one of one surface and the other surface of the board; and embedding a passive device in the cavity.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a cross-sectional view of a circuit board according to a first exemplary embodiment of the present invention;

FIGS. 2A through 2D is a process diagram showing a method for manufacturing the circuit board according to the first exemplary embodiment of the present invention;

FIG. 3 is a cross-sectional view of a circuit board according to a second exemplary embodiment of the present invention;

FIGS. 4A through 5B are process diagrams showing a method for manufacturing the circuit board according to the second exemplary embodiment of the present invention;

FIG. 6 is a cross-sectional view of a circuit board according to a third exemplary embodiment of the present invention; and

FIG. 7 is a cross-sectional view of a circuit board according to a fourth exemplary embodiment of the present invention.

### DETAILED DESCRIPTION OF THE PREFERRED EMBODIMENT

Exemplary embodiments of the present invention will now be described in detail with reference to the accompanying drawings. However, it should be noted that the spirit of the present invention is not limited to the exemplary embodiments set forth herein, and those having skill in the art and understanding the present invention can easily accomplish retrogressive inventions or other exemplary embodiments included in the spirit of the present invention by the addition, modification, and removal of components within the same spirit, but those are to be construed as being included in the spirit of the present invention.

In addition, components having like functions are denoted by like reference numerals throughout the drawings of each exemplary embodiment.

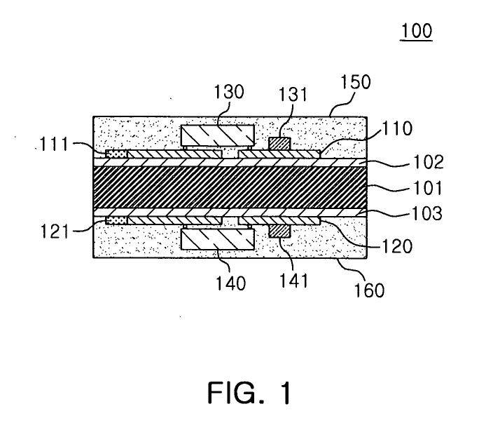

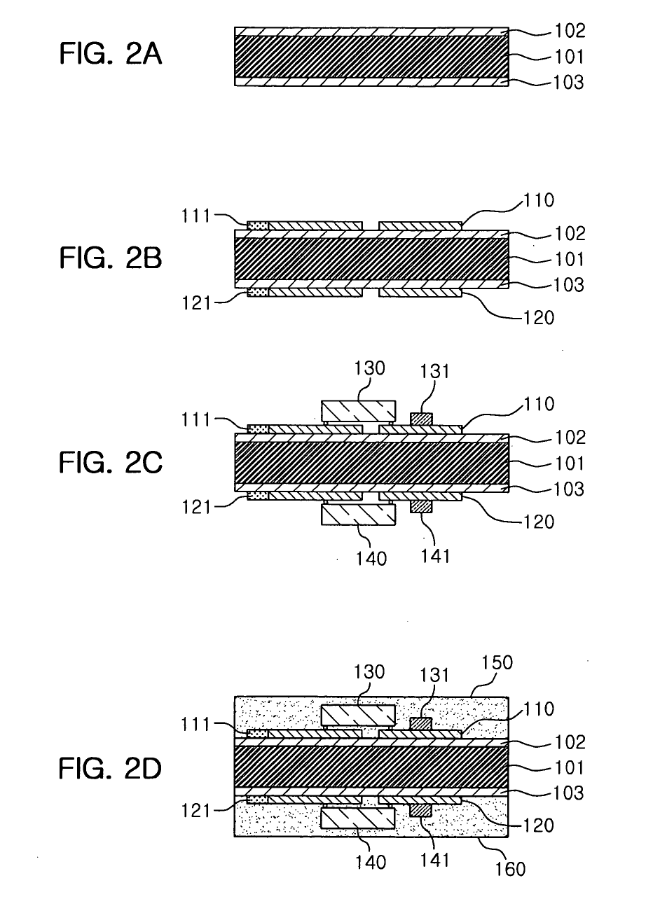

FIG. 1 is a cross-sectional view of a circuit board according to a first exemplary embodiment of the present invention and FIGS. 2A through 2D is a process diagram showing a method for manufacturing the circuit board according to the first exemplary embodiment of the present invention.

Referring to FIGS. 1 through 2D, a circuit board 100 according to a first exemplary embodiment of the present invention may be configured to include a board 101, a first wiring pattern 110, an RF transmitter 111, a second wiring pattern 120, an RF receiver 121, a first semiconductor chip 130, a first passive device 131, a second semiconductor chip 140, a second passive device 141, a first protective layer 150, and a second protective layer 160. However, the first exemplary embodiment describes, by way of example, the case in which the number of wiring patterns, RF transmitters, RF receivers, semiconductor chips, or passive devices is one. This is provided for convenience of explanation only, and therefore, a greater number of components may be provided.

The board 101 may use a silicon board as a double-sided board of which the upper surface and the lower surface have the semiconductor chip or the passive device mounted thereon. Further, the board 100 may use a synthesizing semiconductor such as GaAs, or the like. The thickness of the board 101 may use a thin plate of about 100 to 200 m.

The upper and lower surfaces of the board 101 are provided with a first insulating layer 102 and a second insulating layer 103 to cover the upper and lower surfaces thereof. The first insulating layer 102 and the second insulating layer 103 may be made of an inorganic insulating material, for example, SiO₂.

The first wiring pattern 110 and the second wiring pattern 120 are each formed on the first insulating layer 102 and the second insulating layer 103. The first wiring pattern 110 and the second wiring pattern 120 may be made of metal with excellent conductivity such as Cu, Ni, Al, Ag, Au, or the like and may electrically connect the plurality of semiconductor chips such as transistors configuring a semiconductor circuit, or the like.

The RF transmitter 111 is connected to the first wiring pattern 110 and the RF receiver 121 is connected at a corresponding position of the RF transmitter 111 on the second wiring pattern 120 so that it is formed to be paired with the RF transmitter 111.

The RF transmitter 111 transmits signals of a first semiconductor chip 130 mounted on the first wiring pattern 110 and the RF receiver 121 receives signals from the RF receiver 111 and transmits them to a second semiconductor chip 140 mounted on the second wiring pattern 120. As a result, the first semiconductor chip 130 is electrically connected to the second semiconductor chip 140.

The RF transmitter 111 may be a radiator that applies and radiates a wireless frequency to the signals of the first semiconductor chip 130, for example, an antenna pattern. The antenna pattern may also form a portion of the first wiring pattern 110. Further, the RF transmitter 111 may include an A/D converter that converts DC signals from the first semiconductor chip 130 into AC signals in addition to an antenna pattern.

The RF receiver 121 may be configured of a transceiver that receives signals from the RF transmitter 111 and transmits them to the second semiconductor chip 140.

The first exemplary embodiment describes, by way of example, the case where the antenna pattern or the A/D converter is used as the RF transmitter 111 or the transceiver is used as the RF receiver 121 but the present invention is not limited thereto. The RF transmitter 111 may be constituted by the transceiver and the RF receiver 121 may be constituted by the antenna pattern. In addition to this, various wireless communication modules may be used.

Further, the first exemplary embodiment describes unidirectional communication from the first semiconductor chip 130 to the second semiconductor chip 140 but the present invention is not limited thereto. The wireless communication module for bidirectional communication between the first semiconductor chip 130 and the second semiconductor chip may be used. In addition to this, the wireless communication module for bidirectional communication between the plurality of semiconductor devices 101 mounted on the upper surface of the board 101 and the plurality of semiconductor devices mounted on the lower surface thereof may be used.

In addition to this, the first passive device 131 may be mounted on the first wiring pattern 110 and the second passive device 141 may be mounted on the second wiring pattern 120. As the first passive device 131 and the second passive device 141, a resistor, an inductor, a condenser, or the like, may be used.

The first protective layer 150 is formed on the upper surface of the board 101 in order to cover the first wiring pattern 110, the RF transmitter 111, the first semiconductor chip 130, and the first passive device 131, while the second protective layer 160 is formed on the lower surface of the board 101 in order to cover the second wiring pattern 120, the RF transmitter 111, the second semiconductor chip 140, and the second passive device 141.

The first protective layer 150 and the second protective layer 160 may be made of an insulating resin with excellent electrical insulation, adhesion, thermal shock resistance, and the like, for example, polyimide-based resin, Polyphenyleneoxide-based resin, polybenzoxazole-based resin, or the like.

As described above, since the present invention achieves the electrical connection between the first semiconductor chip 130 and the second semiconductor chip 140 by the unidirectional or bidirectional wireless communication, it can simplify the manufacturing process as compared to the related art that electrically connects them using the TSV or the laser via, thereby making it possible to reduce the manufacturing costs and improve the production efficiency.

A method for manufacturing a circuit board according to a first exemplary embodiment of the present invention having the above-mentioned configuration will now be described.

FIGS. 2A through 2D are process diagrams showing the method for manufacturing the circuit board according to the first exemplary embodiment of the present invention.

As shown in FIG. 2A, the first insulating layer 102 and the second insulating layer 103 are each formed on the upper and lower surfaces of the board 101. The first insulating layer 102 and the second insulating layer 103 may be formed regardless of the sequence thereof. The board 101 may use a silicon wafer and the first insulating layer 102 and the second insulating layer 103 may use a SiO₂ layer.

As shown in FIG. 2B, the first wiring pattern 110 and the second wiring pattern 120 are formed on the first insulating layer 102 and the second insulating layer 103 while the RF transmitter 111 is connected to the first wiring pattern 110 and the RF receiver 121 is connected to the second wiring pattern 120. The first wiring pattern 110 and the second wiring pattern 120 and the formation of the RF transmitter 111 and the RF receiver 121 may be formed regardless of the sequence thereof.

The first wiring pattern 110 and the second wiring pattern 120 may be formed by forming a seed layer (not shown) on the first insulating layer 102 and the second insulating layer 103, applying photoresist to the seed layer, forming an opening part (not shown) by etching a portion in which the first wiring pattern 110 and the second wiring pattern 120 will be formed, and depositing a plating layer on the seed layer by performing an electroplating method on the opening part.

The RF transmitter 111 and the RF receiver 121 may be formed at the signal input and output points of the semiconductor device mounted on the first wiring pattern 110 and the second wiring pattern 120 and may be formed at the position corresponding to each other. In this configuration, when the RF transmitter 111 and the RF receiver 121 are formed of the wiring patterns, they may be formed by the same method as the first wiring pattern 110 and the second wiring pattern 120.

As shown in FIG. 2C, the first semiconductor chip 130, the first passive device 131, the second semiconductor chip 140, and the second passive device 141 are mounted on the first wiring pattern 110 and the second wiring pattern 120, respectively. The process of mounting the first semiconductor chip 130, the first passive device 131, the second semiconductor chip 140, and the second passive device 141 may also be made regardless of sequence.

As shown in FIG. 2D, the protective layer 150 is formed on the first insulating layer 102 in order to cover the first wiring pattern 110, the RF transmitter 111, the first semiconductor chip 130, and the first passive device 131 and the second protective layer 160 is formed on the second insulating layer 103 in order to cover the second wiring pattern 120, the RF receiver 121, the second semiconductor chip 140, and the second passive device 141.

In this configuration, an external connecting terminal (not shown) is formed on the first insulating layer 102 and the second insulating layer 103 and the external connecting terminal may be formed to be exposed at the time of forming the first protective layer 150 and the second protective layer 160. For example, an Al layer is formed as the external connecting terminal by a sputtering method and a polyimide resin layer may be formed as the first protective layer 150 and the second protective layer 160 by a spin coating method, a spray method, a dipping method, or the like.

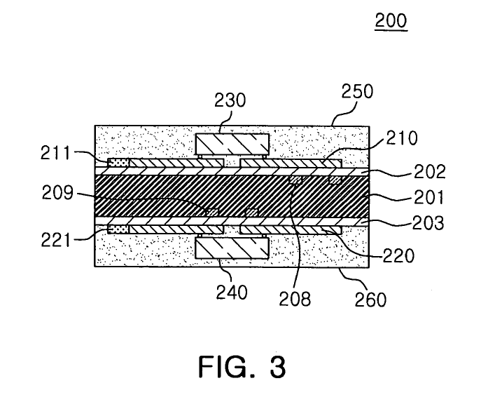

FIG. 3 is a cross-sectional view of a circuit board according to a second exemplary embodiment of the present invention.

A circuit board 200 according to a second exemplary embodiment of the present invention shown in FIG. 3 has a structure in which the passive device is embedded in the inner side of the board. Other components are the same as the circuit board according to the first exemplary embodiment of the present invention shown in FIG. 1 and therefore, a detailed description thereof will be omitted. Hereinafter, only the differences therebetween will be described.

Referring to FIG. 3, the circuit board 200 according to the second exemplary embodiment of the present invention includes a first passive device 208 that is embedded toward the inner side of the board 201 from the upper surface of the board 201 and a second passive device 209 that is embedded toward the inner side of the board 201 from the lower surface of the board 201. As such, a highly-integrated circuit board 200 may be obtained by embedding the passive device into the board 201.

The second exemplary embodiment describes the configuration in which the passive device is embedded in the upper and lower surfaces of the board 201, respectively, but the present invention is not limited thereto. Therefore, the passive device may be formed on any one of the upper surface and the lower surface of the board.

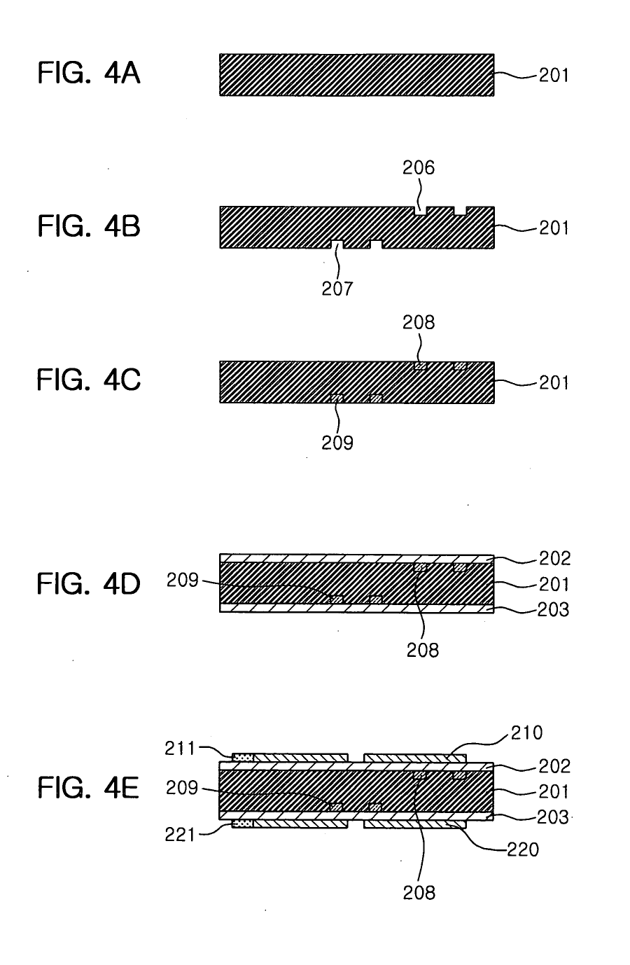

FIGS. 4A through 5B are process diagrams showing the method for manufacturing the circuit board according to the second embodiment of the present invention. The method for manufacturing the circuit board according to the second exemplary embodiment of the present invention will now be described with reference to FIGS. 4A through 5B.

The circuit board 200 according to the second exemplary embodiment of the present invention has a structure in which the passive device is embedded in the inner side of ₜhe board. Other components are the same as the circuit board according to the first exemplary embodiment of the present invention shown in FIG. 1 and therefore, a detailed description thereof will be omitted. Hereinafter, only the differences therebetween will be described.

As shown in FIG. 4A, the board 201 is prepared. As the board 201, the silicon wafer may be used and the glass wafer, or the like, may be used.

As shown in FIG. 4B, a first cavity 206 and a second cavity 207 are each formed to be recessed into the board 201 from the upper and lower surfaces thereof.

The first cavity 206 and the second cavity 207 may be formed by applying the photoresist (not shown) to the upper and lower surfaces of the substrate 201, respectively, forming the opening part (not shown) on the photoresist, etching the substrate 201 by using the opening part as an etch mask layer, and removing the photoresist.

In this configuration, the etching method may use dry or wet etching and the removal of the photoresist may be accomplished through a chemical mechanical polishing (CMP) process. In addition, the photoresist may be removed but may be used as a material of the first insulating layer 202 and the second insulating layer 203 to be described below without being removed.

As shown in FIG. 4C, the first passive device 208 and the second passive 209 are formed in the first cavity 206 and the second cavity 207 that are formed on the upper and lower surfaces of the board 201.

Next, as shown in FIG. 4D, the first insulating layer 202 and the second insulating layer 203 are each formed on the upper and lower surfaces of the board 201. As described above, the first insulating layer 202 and the second insulating layer 203 may use the photoresist without removing the photoresist used as the etch mask at the time of forming the first cavity 206 and the second cavity 207 in the substrate 201.

Next, as shown in FIG. 4E, the first wiring pattern 210 is formed on the first insulating layer 202 and the RF transmitter 211 may be formed to be connected to the first wiring pattern 210. In addition, the second wiring pattern 220 is formed on the second insulating layer 203 and the RF receiver 221 may be formed to connect the RF receiver 221 to the second wiring pattern 220 at the position corresponding to the position of the RF transmitter 211 so that it is formed so as to be paired with the RF transmitter 211.

Next, as shown in FIG. 5A, the first semiconductor chip 230 and the second semiconductor chip 240 are mounted on the first wiring pattern 210 and the second wiring pattern 220, respectively.

Next, as shown in FIG. 5B, the first protective layer 250 is formed on the first insulating layer 202 in order to cover the first wiring pattern 210, and the RF transmitter 211 and the first semiconductor chip 230 and the second protective layer 260 is formed on the second insulating layer 203 in order to cover the second wiring pattern 220, the RF receiver 221, and the second semiconductor chip 240.

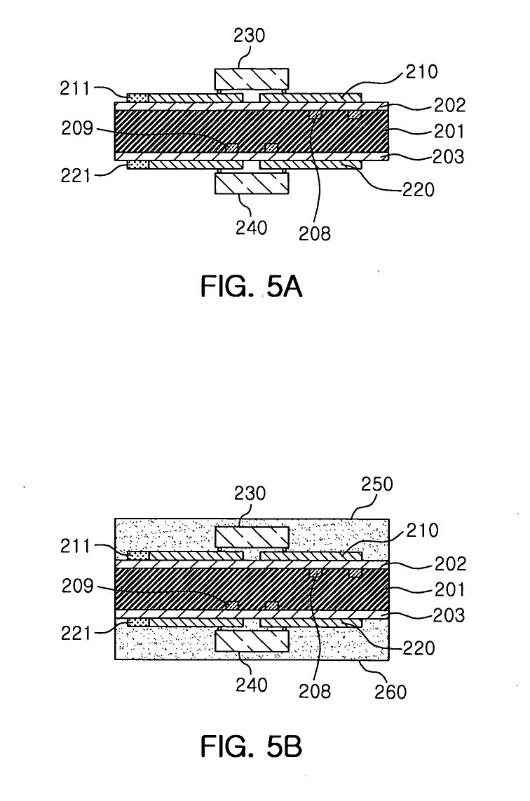

FIG. 6 is a cross-sectional view of a circuit board according to a third embodiment of the present invention. A circuit board according to a third exemplary embodiment will now be described with reference to FIG. 6.

The circuit board 300 according to the third exemplary embodiment of the present invention has a structure in which the board is formed of a plurality of layers. Other components thereof are the same as those of the circuit board according to the first exemplary embodiment of the present invention shown in FIG. 1 and therefore, a detailed description thereof will be omitted. Hereinafter, only the differences therebetween will be described.

Referring to FIG. 6, in the circuit board according to the third exemplary embodiment, the board is formed by stacking a first board 301, a second board 302, and a third board 303. A first insulating layer 304 and a second insulating layer 305 are each formed on the upper surface of the first substrate 301 that forms the top layer and the lower surface of the third substrate 303 that is the bottom layer.

A first wiring pattern 310 and a second wiring pattern 320 are each formed on the first insulating layer 304 and the second insulating layer 305. In order to electrically connect the semiconductor device mounted on the first wiring pattern 310 and the semiconductor device mounted on the second wiring pattern 320, a first RF transmitter 311 and a first RF receiver 321 may be formed at the corresponding position. In this configuration, in order to transmit signals from the semiconductor device mounted on the second wiring pattern 320 to the semiconductor device mounted on the first wiring pattern 310 in addition to transmitting signals from the semiconductor device mounted on the first wiring pattern 310 to the semiconductor device mounted on the second wiring pattern 320, the second RF receiver 312 may be formed on the first wiring pattern 310 and the second RF transmitter 322 may be formed on the second wiring pattern 320.

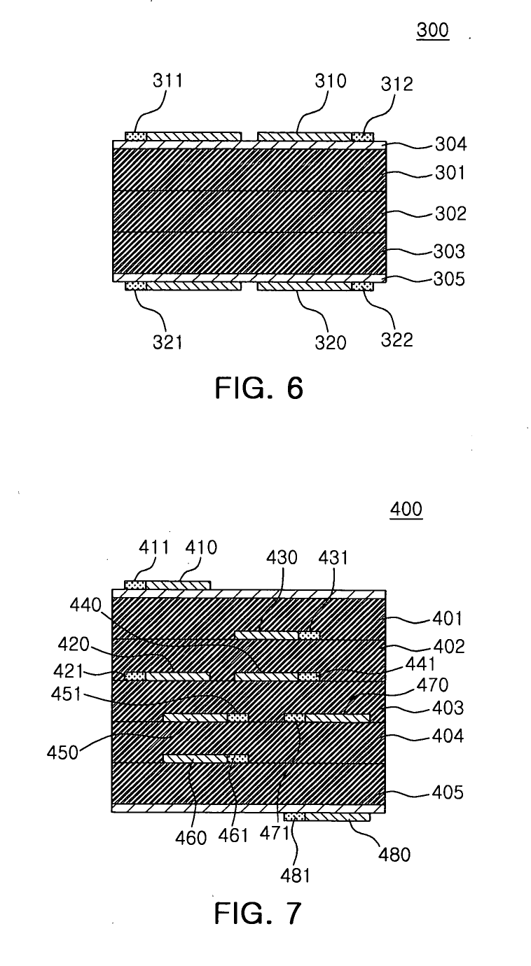

FIG. 7 is a cross-sectional view of a circuit board according to a fourth embodiment of the present invention. A circuit board according to a fourth exemplary embodiment will now be described with reference to FIG. 7.

A circuit board 400 according to the fourth exemplary embodiment has a structure in which the board is formed of a plurality of layers and is different from the circuit board according to the first exemplary embodiment in that the wiring patterns are formed on each layer and the RF transmitter and the RF receiver are formed so as to be paired on any one of the plurality of layers. As a result, only the differences therebetween will be described hereinafter.

Referring to FIG. 7, the circuit board 400 according to the fourth exemplary embodiment maybe a multi-layer ceramic board formed by stacking a first board 401, a second board 402, a third board 403, a fourth board 404, and a fifth board 405. The wiring pattern may be formed on each board and the RF transmitter and the RF receiver may be formed to be paired on the wiring pattern to electrically connect the semiconductor devices mounted or embedded on or into each board.

For example, in order to transmit the signals of the semiconductor device mounted on the first wiring pattern 410 formed on the first board 401 to the semiconductor device mounted on the second wiring pattern 420 formed on the third board 403, the first RF transmitter 411 and the first RF receiver 421 may be formed at the position corresponding to each other on the first wiring pattern 410 and the second wiring pattern 420.

In addition, in order to transmit the signals of the semiconductor device mounted on the third wiring pattern 430 formed on the second board 402 to the semiconductor device mounted on the fourth wiring pattern 440 formed on the third board 403, the second RF transmitter 431 and the second RF receiver 441 may be formed at the position corresponding to each other on the third wiring pattern 430 and the fourth wiring pattern 440, respectively.

In addition, in order to transmit the signals of the semiconductor device mounted on the fifth wiring pattern 450 formed on the fourth board 404 to the semiconductor device mounted on the sixth wiring pattern 460 formed on the fifth board 405, the third RF transmitter 451 and the third RF receiver 451 may be formed at the position corresponding to each other on the fifth wiring pattern 450 and the sixth wiring pattern 460, respectively.

In addition, in order to transmit the signals of the semiconductor device mounted on the seventh wiring pattern 470 formed on the fourth board 404 to the semiconductor device mounted on the eighth wiring pattern 480 formed on the lower surface of the fifth board 405, the third RF transmitter 471 and the third RF receiver 471 may be formed at the position corresponding to each other on the seventh wiring pattern 470 and the eighth wiring pattern 480, respectively.

As described in the fourth exemplary embodiment, the semiconductor devices mounted on each layer are electrically connected to each other by the unidirectional or bidirectional wireless communication between any layers in the multi-layer ceramic board, such that there is no need to perform the process of penetrating through the plurality of layers for the electrical connection between any layers on the multi-layer ceramic board as in the related art, thereby improving the production efficiency.

As set forth above, the circuit board according to the present invention connects both surfaces of the circuit board and each layer of the multi-layer ceramic board in a contactless manner by wireless communication between pairs of RF transmitters and the RF receivers provided on both surfaces of the circuit board and each layer of the multi-layer ceramic board, thereby making it possible to simplify the manufacturing process and reduce the manufacturing costs to increase the production efficiency thereof.

While the present invention has been shown and described in connection with the exemplary embodiments, it will be apparent to those skilled in the art that modifications and variations can be made without departing from the spirit and scope of the invention as defined by the appended claims.

What is claimed is:

1. A circuit board, comprising:
a first wiring pattern that is formed on one surface of the board;
a second wiring pattern that is formed on the other surface of the board;
an RF transmitter that is formed on one surface of the board and is connected to the first wiring pattern; and
an RF receiver that is formed on the other surface of the board to be paired with the RF transmitter and is connected to the second wiring pattern,
wherein the first wiring pattern and the second wiring pattern are electrically connected to each other by wireless communication from the RF transmitter to the RF receiver.

2. The circuit board of claim 1, wherein the RF transmitter is an antenna and the RF receiver is a transceiver.

3. The circuit board of claim 1, wherein the RF receiver is formed at a position corresponding the position of the RF transmitter.

4. The circuit board of claim 1, further comprising a cavity that is formed toward the inner side of the board from at least one of one surface and the other surface of the board,
wherein a passive device is embedded in the cavity.

5. The circuit board of claim 1, wherein a protective layer is formed on the upper and lower surfaces of the board to cover the first wiring pattern, the second wiring pattern, the RF transmitter, and the RF receiver.

6. A circuit board, comprising:
a plurality of ceramic sheets that are sequentially stacked;
a plurality of wiring patterns that are formed on any one of the plurality of ceramic sheets;
an RF transmitter that is connected to a wiring pattern formed on one of any ceramic sheets and transmits signals from a wiring pattern formed on one sheet; and
an RF receiver that is connected to a wiring pattern formed on the other sheet of any ceramic sheets and is formed at a position corresponding to the RF transmitter to receive signals from the RF transmitter and transmit them to the wiring pattern formed on the other sheet.

7. The circuit board of claim 6, wherein one sheet is a ceramic sheet that forms the top layer of the plurality of ceramic sheets,
the other sheet is a ceramic sheet that forms the bottom layer of the plurality of ceramic sheets, and
the electrical signals between the wiring pattern formed on the ceramic sheet that forms the top layer and the wiring pattern formed on the ceramic sheet that forms the bottom layer are exchanged with each other by wireless communication from the RF transmitter to the RF receiver.

8. A method for manufacturing a circuit board, comprising
forming a first wiring pattern and an RF transmitter connected to the first wiring pattern on one surface of a board; and
forming a second wiring pattern and an RF receiver connected to the second wiring pattern and formed to be paired with the RF transmitter on the other surface of the board,
wherein the first wiring pattern is electrically connected to the second wiring pattern by wireless communication from the RF transmitter to the RF receiver.

9. The method for manufacturing a circuit board of claim 8, further comprising:
forming a cavity toward the inner side of the board from at least one of one surface and the other surface of the board; and
embedding a passive device in the cavity.
